(19) United States
(12) Patent Application Publication
(10) Pub. No.: US 2003/0161123 A1
(43) Pub. Date: Aug. 28, 2003

(54) BONDING STRUCTURE FOR BONDING SUBSTRATES BY METAL STUDS

(76) Inventors: Ho-Ming Tong, Taipei (TW); Chun-Chi Lee, Kaohsiung (TW); Jen-Kuang Fang, Pingtung Hsien (TW); Min-Lung Huang, Kaohsiung (TW); Jau-Shoung Chen, Hsinchu Hsien (TW); Ching-Huei Su, Kaohsiung (TW); Chao-Fu Weng, Tainan (TW); Yung-Chi Lee, Kaohsiung (TW); Yu-Chen Chou, Kaohsiung (TW); Tsung-Hua Wu, Kaohsiung Hsien (TW); Su Tao, Kaohsiung (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/248,405

(22) Filed: Jan. 16, 2003

(30) Foreign Application Priority Data
Feb. 27, 2002 (TW) 91103527

(51) Int. Cl. H05K 7/10; H05K 7/12

(52) U.S. Cl. 361/767

(57) ABSTRACT

A bonding structure for bonding two substrates by a metal stud includes a first substrate, a second substrate, at least a metal stud and an adhesive. The bonding structure includes a first substrate, a second substrate, at least a metal stud and an adhesive. The metal stud is arranged between the first substrate and the second substrate and attached to the first substrate. The adhesive is applied between the metal stud and the second substrate to electrically connect the metal stud and the second substrate.

### CROSS REFERENCE TO RELATED APPLICATIONS

This application claims the priority benefit of Taiwan application serial no. 91103527, filed on Feb. 27, 2002, the full disclosure of which is incorporated herein by reference.

### BACKGROUND OF INVENTION

1. Field of the Invention

The present invention relates to a bonding structure for bonding substrates by metal studs. More specifically, the present invention relates to a bonding structure for bonding substrates by metal studs, in which problems caused from heat expansion of the substrates can be solved.

2. Description of the Related Art

Heat dissipation performance and CTE (coefficient of thermal expansion) mismatch are critical factors to consider reliability of a semiconductor package. For example, when a ceramic substrate is bonded to a printed circuit board (PCB) via solder balls, the CTE difference between the ceramic substrate and the PCB results in the separation of the solder balls from PCD or the ceramic substrate. U.S. Pat. No. 6,297,559 discloses an approach for solving the problem caused by CTE mismatch between of the ceramic substrate and the PCB.

FIG. 1 is a schematic view of a solder bonding structure disclosed in U.S. Pat. No. 6,297,559. In the solder bonding structure, the reference numeral 110 refers to a ceramic substrate, the reference numeral 120 refers to a PCB, the reference numeral 130 refers to a solder ball, the reference numeral 140 refers to a conductive paste, and the reference numeral 150 refers to a solder. The ceramic substrate 110 has a plurality of substrate contacts 112. In order to simplify the description thereof, only one substrate contact 112 is shown. The PCB 120 has plurality of PCB contacts 122 (only one is shown). The solder balls 130 are respectively connected to the substrate contacts 112 through the conductive paste 140. The solder balls 130 are respectively connected to the PCB contacts 122 via the solder 150. In the above structure, since the conductive paste 140 with excellent flexibility is applied between the substrate contacts 112 and the solder balls 130, the problem caused by the CTE mismatch can be solved.

FIG. 2 is a schematic view of another solder bonding structure disclosed in U.S. Pat. No. 6,297,559. In this case, a conductive paste 160 is used instead of the solder 150 to fill between the solder balls 130 and the PCB contacts 122.

However, the conductivity of the conductive paste is usually not as good as desired. The conductivity of the solder bonding structure therefore will be adversely affected if the conductive paste is replaced with the solder. In order to keep the ceramic substrate away from the PCB, the solder balls therebetween should be large enough, and the pitch between the solder balls therefore needs to be sufficient to prevent the solder balls from contacting one another. Therefore, the substrate and the PCB has to be enlarged, or the contact density of the semiconductor package is low. Unfortunately, it can not meet the requirement of a high-density ball grid array (BGA) package.

### SUMMARY OF INVENTION

In one aspect of the present invention, a bonding structure for bonding substrates by metal studs is provided, which not only solves problems of CTE mismatch, but also provides good electrical conductivity.

In another aspect of the present invention, a bonding structure for bonding substrates by metal studs is provided, in which a pitch between adjacent substrates can be reduced. When the bonding structure of the invention is used in a ball grid array, more metal studs can be formed on the substrate and the PCB with a given size compared to a convention package.

In the invention, the term “on” refers to more broad definition for space. For example, when “A is on B” is described, it means that A is directly on B in a manner that A contacts B, or A is above B in a manner that A does not contact B.

In order to achieve the above and other objectives of the invention, a bonding structure for bonding substrates by metal studs is provided. The bonding structure includes a first substrate, a second substrate, at least a metal stud and an adhesive. The metal stud is arranged between the first substrate and the second substrate and attached to the first substrate. The adhesive is applied between the metal stud and the second substrate to electrically connect the metal stud and the second substrate.

According to one preferred embodiment of the invention, the first substrate is a ceramic substrate, and the second substrate is a PCB. The adhesive is a solder or conductive paste. The material for the metal stud is lead-rich alloy with the content of lead being higher than 90 vol. %. The material for the metal stud is selected from the group of 90Pb/10Sn solder, 95Pb/5Sn solder and 97Pb/3Sn solder, for example.

In view of the foregoing, the bonding structure including the metal stud and the adhesive for bonding two substrates or carriers has a very fine pitch between the metal studs. Therefore, the contact density of the substrate can be increased with a given substrate size. The metal studs are made higher to increase the distance between the substrate and the PCB, without increasing the diameter of the metal stud. Therefore, the slim metal stud can withstand larger transversal deformation so that the CTE mismatch between the substrate and the PCB can be tolerated. The adhesive can be a solder that provides good electrical conductivity when bonded to the metal stud.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principle of the invention. In the drawings,

FIG. 1 is a schematic view of a solder bonding structure disclosed in U.S. Pat. No. 6,297,559;

FIG. 2 is a schematic view of another solder bonding structure disclosed in U.S. Pat. No. 6,297,559;

FIG. 3 is a cross-sectional view of a metal stud bonding structure according to a preferred embodiment of the invention; and

FIG. 4 is a schematic view of a semiconductor package according to one preferred embodiment of the invention.

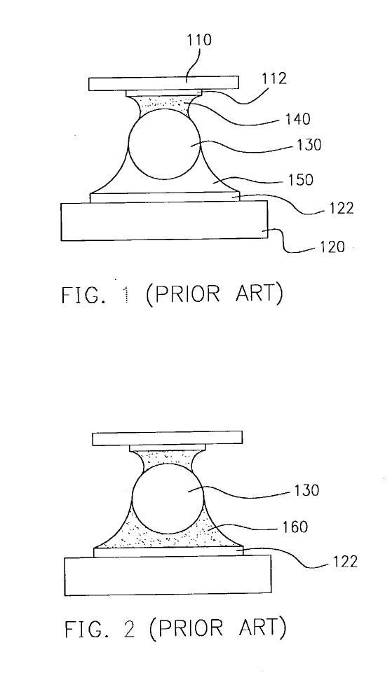

### DETAILED DESCRIPTION

Reference will now be made in detail to the present preferred embodiments of the invention, examples of which are illustrated in the accompanying drawings. Whenever possible, the same reference numbers are used in the drawings and the description to refer to the same or like parts.

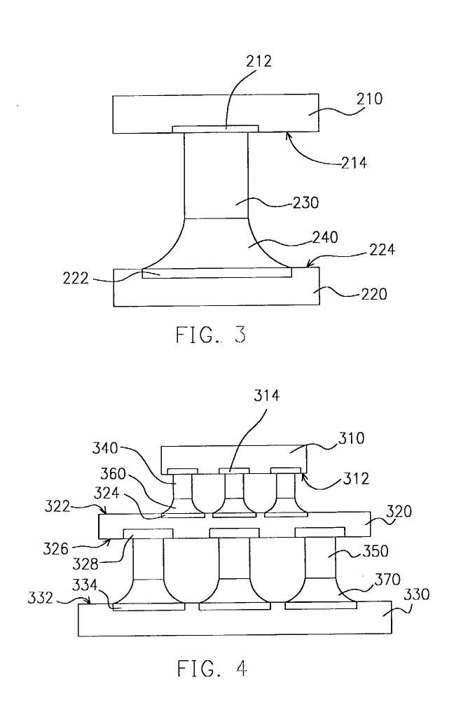

FIG. 3 is a cross-sectional view of a metal stud bonding structure according to a preferred embodiment of the invention. As shown, the reference numeral 210 refers to a substrate. The substrate 210 can be a ceramic substrate. The reference numeral 220 refers to a printed circuit board (PCB). The reference numeral 230 refers to a metal stud. The reference numeral 240 refers to an adhesive. The ceramic substrate 210 has a connection surface 214 and a plurality of connections 212 on the connection surface 214. For simplifying the description of the structure, only one connection 212 is shown in FIG. 3. The PCB 220 has a contact surface 224 and a plurality of contacts 222 on the contact surface 224. In order to simplify the description of the structure, only one contact 222 is shown in FIG. 3.

The stud bump 230 is formed on the connection 212. There are two methods to form the stud bump 230. One of the methods includes steps of thermally pressing a metal sheet (not shown) to the connection surface 214 of the substrate 210, and then photolithographically etching the metal sheet to define a plurality of the stud bumps 230 (only one stud bump is shown). The other method includes steps of sputtering or vaporizing an adhesive layer (not shown) on the connection surface 214, forming a photoresist over the adhesive layer, photolithographically etching the adhesive layer to define a plurality of photoresist openings, forming a plurality of stud bumps 230 respectively in the photoresist openings by plating, removing the photoresist after the stud bumps are electrically connected to the adhesive layer, and removing the adhesive layer exposed by the stud bumps 230. The material of the stud bump 230 is a high-melting-point material, for example, a tin lead alloy with high lead content. An example of the tin lead alloy with high lead content includes a tin lead alloy with more than 90 vol. % of lead, such as tin lead alloy with Pb/Sn ratio of 90/10 (hereinafter referred to as 90Pb/10Sn alloy), tin lead alloy with Pb/Sn ratio of 95/5 (hereinafter referred to as 95Pb/5Sn alloy) and tin lead alloy with Pb/Sn ratio of 97/3 (hereinafter referred to as 97Pb/3Sn alloy). The stud bump 230 is bonded to the contact 224 by means of the adhesive 240. The adhesive 240 is a low-melting-point material such as a low-melting-point solder or a low-curing-temperature conductive adhesive, so that when the adhesive 240 is heated, the stud bump 230 would not be melted. Thereby, the ceramic substrate 210 is electrically connected to the ceramic substrate 210. Although the materials of the stud bump 230 and the adhesive 240 have been specifically recited above, other metal or alloy materials can be also used. When the adhesive 240 is an electrically conductive adhesive, the melting point of the stud bump 230 should be higher than the curing temperature of the adhesive 240. When the adhesive 240 is a metallic material, the melting point of the stud bump is higher than that of the adhesive 240.

In the bonding structure for bonding the substrates by metal studs according to the invention, the stud bump 230 has a small radius, and the pitch between the adjacent stud bumps 230 is reduced. For a given size of the ceramic substrate 210 and the PCB 220, a pitch between the adjacent connections 212 and a pitch between the adjacent contacts 222 are correspondingly reduced, and therefore high-density packaging is achieved. Furthermore, since the stud bump 230 has a small radius and further the pitch between the adjacent stud bumps 230 is reduced, the stud bumps 230 therefore can endure more transversal stress and thus more deformation due to the CTE mismatch between the ceramic substrate 210 and the PCB 220.

Furthermore, since the adhesive 240 can be a solder and the metal stud 230 is made of metal, the bonding structure of the adhesive 240 and the metal stud 230 has good electrical conductivity.

FIG. 4 is a schematic view of a semiconductor package according to one preferred embodiment of the invention. The semiconductor package includes a chip 310, a first substrate 320, a second substrate 330, a plurality of first metal studs 340 and a plurality of second metal studs 350. The chip 310 has an active surface 312 and a plurality of bonding pads 314 on the active surface 312. The first substrate 320 can be a ceramic substrate. The first substrate 320 has a first surface 322 and a second surface 326. A plurality of first contacts 324 are formed on the first surface 322 of the first substrate 320. A plurality of second contacts 328 are formed on the second surface 326 of the first substrate 320. The second substrate 330 can be a printed circuit board (PCB). The second substrate 330 has a third surface 332 on which a plurality of second contacts 334 are formed.

Furthermore, the first metal studs 340 are formed on the active surface 312 of the chip 310 by photolithography techniques and respectively electrically connected to the corresponding bonding pads 314. The first metal studs 340 are attached to the first contacts 324 of the first substrate 320 via a first adhesive 360. The first metal studs 340 can be made of lead-rich tin/lead alloy in which the content of lead in the first metal studs 340 is higher than 90 vol. %. The lead-rich tin/lead alloy can be 90Pb/10Sn alloy, 95Pb/5Sn alloy and 97Pb/3Sn alloy. The materials of the first metal stud 340 and the first adhesive 360 are not limited to those recited above, and other metal or alloy can be used. It is noted that the melting point of the first metal stud 340 is higher than an adhesion temperature of the first adhesive 360. When the first adhesive 360 is a conductive paste, the melting point of the first metal stud 340 is higher than the curing temperature of the first adhesive 360. When the first adhesive 360 is made of a metal material, the melting point of the first metal stud 340 is higher than that of the first adhesive 360.

Furthermore, no matter which metal stud forming method is used, the second metal studs 350 are respectively formed on the second contacts 328. Then, the second metal studs 350 are respectively bonded to the corresponding third contacts 334 of the second substrate 330 via a second adhesive 370. The second metal stud 350 can be made of lead-rich tin/lead alloy. That is, the content of lead in the second metal studs 350 is higher than 90 vol. %. The lead-rich tin/lead alloy can be 90Pb/10Sn alloy, 95Pb/5Sn alloy or 97Pb/3Sn alloy. The materials of the second metal stud 350 and the second adhesive 370 are not limited to those recited above, and other metal or alloy can be used. It is noted that the melting point of the second metal stud 350 is higher than an adhesion temperature of the second adhesive 370. When the second adhesive 370 is a conductive paste, the melting point of the second metal stud 350 is higher than the curing temperature of the second adhesive 370. When the second adhesive 370 is made of a metal material, the melting point of the second metal stud 350 is higher than that of the second adhesive 370.

The bonding structure including the metal stud and the adhesive according to the invention can be applied to any carrier, and is not only limited to the chip and the substrate.

In view of the foregoing, the invention has the following advantages:

1. The bonding structure including the metal stud and the adhesive for bonding two substrates or carriers has a very fine pitch between the metal studs. Therefore, the contact density of the substrate can be increased with a given substrate size.

2. In the bonding structure including the metal stud and the adhesive for bonding two substrates or carriers, the metal studs are made higher to increase the distance between the substrate and the PCB without increasing the diameter of the metal stud. Further, the slim metal stud can withstand larger transversal deformation so that the CTE mismatch between the substrate and the PCB can be better tolerated.

3. In the bonding structure including the metal stud and the adhesive for bonding two substrates or carriers, the adhesive can be a solder that provides good electrical conductivity when bonded to the metal stud.

It will be apparent to those skilled in the art that various modifications and variations can be made to the structure of the present invention without departing from the scope or spirit of the invention. In view of the forgoing, it is intended that the present invention cover modifications and variations of this invention provided they fall within the scope of the following claims and their equivalents.

1. A bonding structure for bonding two substrates by a metal stud, the bonding structure comprising:
a first substrate;
a second substrate;
at least a metal stud arranged between the first substrate and the second substrate, wherein a first end of the metal stud is attached to the first substrate; and
an adhesive applied between a second end of the metal stud and the second substrate to electrically connect the metal stud and the second substrate, wherein a melting point of the metal stud is higher than an adhesion temperature of the adhesive.

2. The bonding structure of claim 1, wherein the first substrate is a ceramic substrate.

3. The bonding structure of claim 1, wherein the second substrate is a PCB.

4. The bonding structure of claim 1, wherein the adhesive is a solder.

5. The bonding structure of claim 1, wherein the adhesive is a conductive paste.

6. The bonding structure of claim 1, wherein the material for the metal stud is lead-rich alloy with the content of lead being higher than 90 vol. %.

7. The bonding structure of claim 6, wherein the material for the metal stud is selected from the group consisting of 90Pb/10Sn solder, 95Pb/5Sn solder and 97Pb/3Sn solder.

8. A bonding structure having a carrier with a metal stud thereon, the bonding structure comprising:
a carrier; and
at least a metal stud arranged on the carrier, wherein the material for the metal stud is lead-rich alloy with the content of lead being higher than 90 vol. %.

9. The bonding structure of claim 8, wherein the carrier is a substrate.

10. The bonding structure of claim 8, wherein the carrier is a semiconductor chip.

11. The bonding structure of claim 8, wherein the material for the metal stud is selected from the group consisting of 90Pb/10Sn solder, 95Pb/5Sn solder and 97Pb/3Sn solder.

12. A semiconductor package comprising:
a semiconductor chip;
a first substrate;
at least a first metal stud located between the semiconductor chip and the first substrate, wherein a first end of the metal stud is attached to the semiconductor chip;
a first adhesive applied between a second end of the first metal stud and the first substrate to electrically connect the metal stud and the second substrate, wherein a melting point of the first metal stud is higher than an adhesion temperature of the first adhesion temperature;
a second substrate;
at least a second metal stud located between the first substrate and the second substrate, wherein a first end of the second metal stud is attached to the first substrate; and
a second adhesive applied between a second end of the second metal stud and the substrate to electrically connect the second metal stud and the second substrate, wherein a melting point of the second metal stud is higher than an adhesion temperature of the second adhesive.

13. The bonding structure of claim 12, wherein the first substrate is a ceramic substrate.

14. The bonding structure of claim 12, wherein the second substrate is a PCB.

15. The bonding structure of claim 12, wherein the first adhesive is a solder.

16. The bonding structure of claim 12, wherein the first adhesive is a conductive paste.

17. The bonding structure of claim 12, wherein the second adhesive is a solder.

18. The bonding structure of claim 12, wherein the second adhesive is a conductive paste.

19. The bonding structure of claim 12, wherein the material for the first metal stud is lead-rich alloy with the content of lead being higher than 90 vol. %.

20. The bonding structure of claim 19, wherein the material for the first metal stud is selected from the group consisting of 90Pb/10Sn solder, 95Pb/5Sn solder and 97Pb/3Sn solder.

21. The bonding structure of claim 12, wherein the material for the second metal stud is lead-rich alloy with the content of lead being higher than 90 vol. %.

22. The bonding structure of claim 21, wherein the material for the second metal stud is selected from the group consisting of 90Pb/10Sn solder, 95Pb/5Sn solder and 97Pb/3Sn solder.
